(19) United States
(12) Patent Application Publication
(10) Pub. No.: US 2026/0186459 A1
(43) Pub. Date: Jul. 2, 2026

(54) APPARATUS AND METHOD FOR PROCESSING SUBSTRATE

(71) Applicant: SEMES CO., LTD., Cheonan-si (KR)

(72) Inventors: Seung Un OH, Cheonan-si (KR); Myung Chan CHO, Asan-si (KR)

(21) Appl. No.: 19/385,176

(22) Filed: Nov. 11, 2025

(30) Foreign Application Priority Data
Dec. 26, 2024 (KR) 10-2024-0197178

(51) Int. Cl. G05B 15/02; H01L 21/677

(52) U.S. Cl. CPC G05B 15/02; H10P 72/3411

(57) ABSTRACT

A substrate processing apparatus includes an index unit configured to unload a substrate from a container storing the substrate; and a control unit configured to control the index unit. The index unit is configured to unload the substrate from the container at a predetermined time interval, and to close a door of the container after unloading the substrate.

### CROSS-REFERENCE TO RELATED APPLICATION(S)

This application claims benefit of priority to Korean Patent Application No. 10-2024-0197178 filed on Dec. 26, 2024 in the Korean Intellectual Property Office, the disclosure of which is incorporated herein by reference in its entirety.

### BACKGROUND

### 1. Field

The present disclosure relates to a substrate processing apparatus and a substrate processing method for processing a substrate.

### 2. Description of Related Art

In order to manufacture a semiconductor device, various processes, such as a photolithography process, an etching process, a deposition process, an ion implantation process, and a cleaning process, may be performed on a semiconductor silicon wafer (hereinafter referred to as a “substrate”). A substrate supplied to each process may be sensitive to temperature and humidity, and thus may be transported or stored using a storage container such as a front opening unified pod (FOUP). The storage container may have a structure capable of safely fixing and protecting a substrate.

The storage container may be transported to a substrate processing apparatus of each process by a transfer means such as an overhead transfer, an overhead conveyor, or an automatic guided vehicle, or by an operator. A substrate transported to a substrate processing apparatus of each process through the storage container may be processed according to a process of the substrate processing apparatus, but collapse of fine patterns may occur due to a humidity change of the substrate. Accordingly, in order to manage humidity of the substrate, scheduling of unloading the substrate from the storage container may be required to minimize a time during which the substrate is exposed externally.

### SUMMARY

An aspect of the present disclosure is to provide a substrate processing apparatus and a substrate processing method for unloading a substrate from a storage container so as to minimize external contact time of the substrate.

According to an aspect of the present disclosure, there is provided a substrate processing apparatus including an index unit configured to unload a substrate from a container storing the substrate; and a control unit configured to control the index unit. The index unit may be configured to unload the substrate from the container at a predetermined time interval, and to close a door of the container after unloading the substrate.

According to another aspect of the present disclosure, there is provided a substrate processing method including determining a predetermined time interval, unloading a substrate from a container storing the substrate at the predetermined time interval, and closing a door of the container after unloading the substrate.

The substrate processing method may further include not unloading the substrate when no available chamber is present in a substrate processing apparatus at a point in time at which the substrate is unloaded from the container.

The substrate processing method may further include resetting the predetermined time interval, when the number of available chambers in the substrate processing apparatus is changed at a point in time at which the substrate is unloaded from the container.

In the substrate processing method, the predetermined time interval may be determined based on a time during which the substrate is unloaded from the container and transferred in the substrate processing apparatus, and a time during which the substrate is processed by a predetermined process of the substrate processing apparatus.

In the substrate processing method, the predetermined time interval may be determined based on the number of available chambers of the substrate processing apparatus.

In the substrate processing method, a processed substrate may be loaded into a storage container, may be maintained in a standby state until a unloading time of a subsequent substrate without closing a door of the container when a remaining time until the unloading time of the subsequent substrate is less than a predetermined time after the substrate is loaded, and may be unloaded at the unloading time of the subsequent substrate and then the door of the container may be closed.

According to another aspect of the present disclosure, there is provided a substrate processing apparatus including a processor, and a memory storing an instruction executed by the processor. When the processor executes the instruction stored in the memory, the processor may be configured to unload a substrate from a container storing the substrate at a predetermined time interval, and to close a door of the container such that a substrate remaining in the container is not in contact with the outside of the container, after unloading the substrate.

A substrate processing apparatus or a substrate processing method according to an example embodiment of the present disclosure may manage humidity of a substrate by unloading the substrate from a storage container so as to minimize external contact time of the substrate. Collapse of fine patterns of the substrate may be prevented by managing the humidity of the substrate. In addition, a time during which the substrate is in a standby state in a process chamber may be reduced, thereby reducing edge defects of the substrate, and minimizing usage of a chemical solution used during substrate processing.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic plan configuration diagram illustrating a substrate processing apparatus according to an example embodiment of the present disclosure;

FIG. 2 is a schematic diagram illustrating an arrangement of a process chamber of a substrate processing apparatus according to an example embodiment of the present disclosure;

FIG. 3 is a flowchart illustrating a portion of an operation of a substrate processing apparatus according to an example embodiment of the present disclosure;

FIG. 4 is a flowchart illustrating a portion of an operation of a substrate processing apparatus according to an example embodiment of the present disclosure;

FIG. 5 is a flowchart illustrating a portion of an operation of a substrate processing apparatus according to an example embodiment of the present disclosure;

FIG. 6 is an exemplary diagram illustrating an operation timing of a substrate processing apparatus according to the related art;

FIG. 7 is an exemplary diagram illustrating an operation timing of a substrate processing apparatus according to an example embodiment of the present disclosure;

FIG. 8 is an exemplary diagram illustrating an operation timing of a substrate processing apparatus according to an example embodiment of the present disclosure; and

FIG. 9 is a block diagram illustrating a computing device capable of fully or at least partially implementing a control unit of a substrate processing apparatus according to an example embodiment of the present disclosure.

### DETAILED DESCRIPTION

Hereinafter, preferred example embodiments will be described in detail, such that the disclosure could be easily carried out. In describing example embodiments of the present disclosure, when it is determined that a detailed description of a known technology related to the present disclosure may unnecessarily obscure the gist of the present disclosure, a detailed description thereof will be omitted. In addition, the same reference numerals are used throughout the drawings with respect to components having similar functions and actions. In addition, in the present specification, terms such as “upper,” “upper portion,” “upper surface,” “lower,” “lower portion,” “lower surface,” and “side surface” are based on the drawings, may vary depending on a direction in which an element or component is actually arranged.

In addition, it will be understood that “comprises,” “comprising,” “includes,” and “including” specify the presence of stated features, integers, operations, operations, elements, components or a combination thereof, but do not preclude the presence or addition of one or more other features, integers, operations, operations, elements, components, and/or groups thereof.

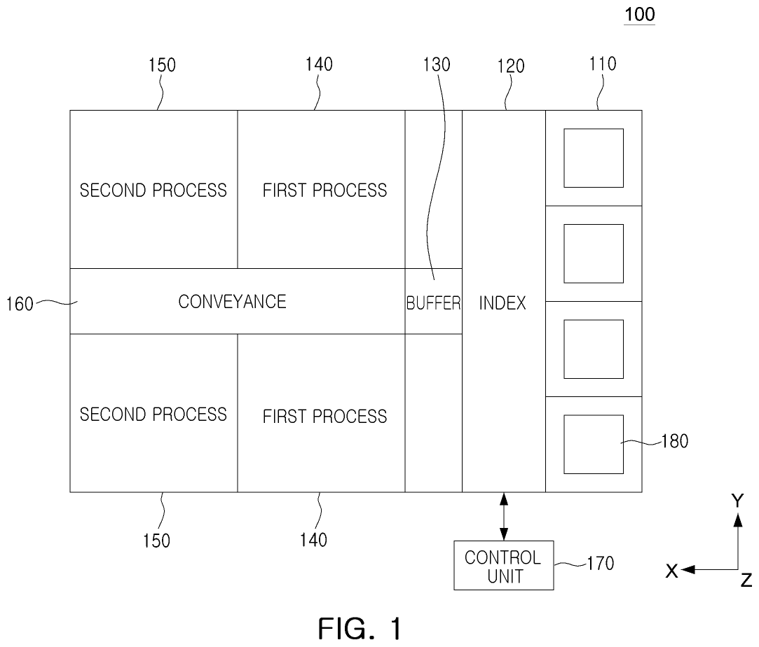

FIG. 1 is a schematic plan configuration diagram illustrating a substrate processing apparatus 100 according to an example embodiment of the present disclosure. Referring to FIG. 1, the substrate processing apparatus 100 may include a load port 110, an index unit 120, a buffer unit 130, a first process unit 140, a second process unit 150, a conveyance unit 160, and a control unit 170. In an example embodiment, a direction in which the index unit 120, the first process unit 140, and the second process unit 150 are sequentially arranged may be referred to as an X-direction, a width direction of the substrate processing apparatus 100 when viewed from above may be referred to as a Y-direction, and a direction, perpendicular to both the X-direction and the Y-direction, may be referred to as a Z-direction.

A container 180 in which a substrate W is accommodated may be disposed on the load port 110. The load port 110 may be provided as a plurality of load ports 110, and the plurality of load ports 110 may be arranged in the Y-direction.

The container 180 may be a sealed container such as a front opening unified pod (FOUP). The container 180 may be disposed on the load port 110 by a transfer means (not illustrated) such as an overhead transfer, an overhead conveyor, or an automatic guided vehicle, or by an operator.

The index unit 120 may unload the substrate W from the container 180 in which the substrate W is accommodated and convey the substrate W to the process units 140 and 150, and may load the substrate W processed by the process units 140 and 150 into the container 180. To this end, the index unit 120 may open and close a door of the container 180 disposed on the load port 110.

An index robot (not illustrated) may be provided in the index unit 120. A guide rail may be provided in the Y-direction within the index unit 120, and the index robot may be provided to be movable on the guide rail. The index robot may include a hand on which the substrate W is disposed, and the hand may be provided to be movable forward and backward, to be rotatable using the Z-direction as an axis, and to be movable in the Z-direction. A plurality of hands may be provided to be spaced apart in a vertical direction, and the hands may independently move forward and backward.

The buffer unit 130 may be provided between the index unit 120 and the conveyance unit 160, and may provide a space in which the substrate W conveyed between the index unit 120 and the process units 140 and 150 temporarily stays. A plurality of buffer slots may be provided in the buffer unit 130, and the substrate W may be disposed in the buffer slots. For example, the index robot may unload the substrate W from the container 180 and dispose the substrate W in the buffer slot, and may load the substrate W from the buffer slot into the container 180.

The process units 140 and 150 may sequentially perform a chemical solution process and a drying process using a process fluid. For example, a cleaning process may be performed by the first process unit 140, and a supercritical drying process may be performed by the second process unit 150. However, such a configuration is merely an example and is not limited thereto, and the first process unit 140 and the second process unit 150 may perform other processes. For example, the first process unit 140 and the second process unit 150 may sequentially perform a developing process and a supercritical drying process, respectively.

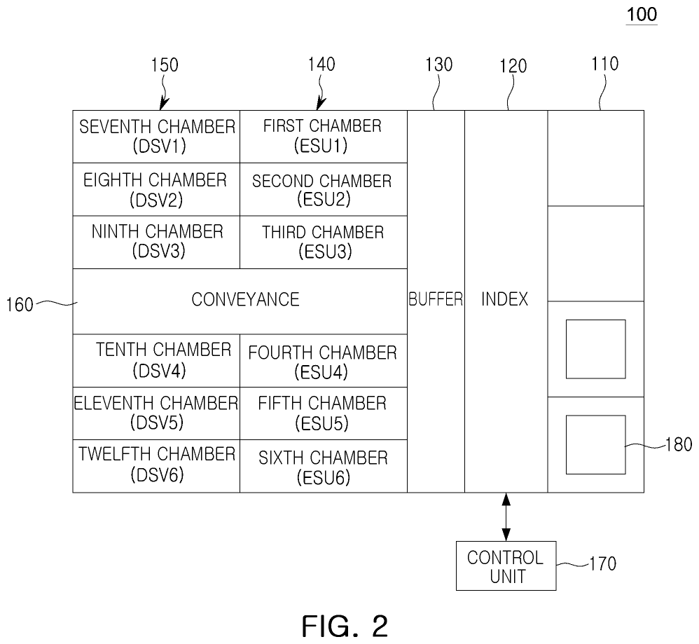

The first process unit 140 and the second process unit 150 may be arranged on one side along the conveyance unit 160, or may be arranged to oppose each other on different sides of the conveyance unit 160. In addition, the first process unit 140 and the second process unit 150 may be provided as a plurality of chambers. An arrangement of the first process unit 140 and the second process unit 150 is not limited to the above examples and may be changed in consideration of a footprint or process efficiency of the substrate processing apparatus 100. An example of an arrangement of process chambers of the first process unit 140 and the second process unit 150 will be described with reference to FIG. 2.

The conveyance unit 160 may convey the substrate W between the buffer unit 130, the first process unit 140, and the second process unit 150, which are arranged around the conveyance unit 160. The conveyance unit 160 may include a conveyance robot and a transfer rail. A guide rail provided in the X-direction, a length direction, may be provided within the conveyance unit 160, and the conveyance robot may be provided to be movable on the guide rail. The conveyance robot may move on the transfer rail and convey the substrate W. The conveyance robot may withdraw the substrate W disposed in the buffer slot and convey the substrate W to the first process unit 140 or the second process unit 150, and may convey the substrate W processed by the first process unit 140 or the second process unit 150 to the buffer slot.

The conveyance robot may include hands on which the substrate W is disposed, and the hands may be provided to be movable forward and backward, to be rotatable using the Z-direction as an axis, and to be movable in the Z-direction. The hands may be provided to be spaced apart from each other in a vertical direction, and the hands may independently move forward and backward. The index robot of the index unit 120 and the conveyance robot of the conveyance unit 160 may be distinguished from each other by name, but the index robot and the conveyance robot may be the same or similar in terms of operation and form. In addition, a mechanism of a known technology may be applied.

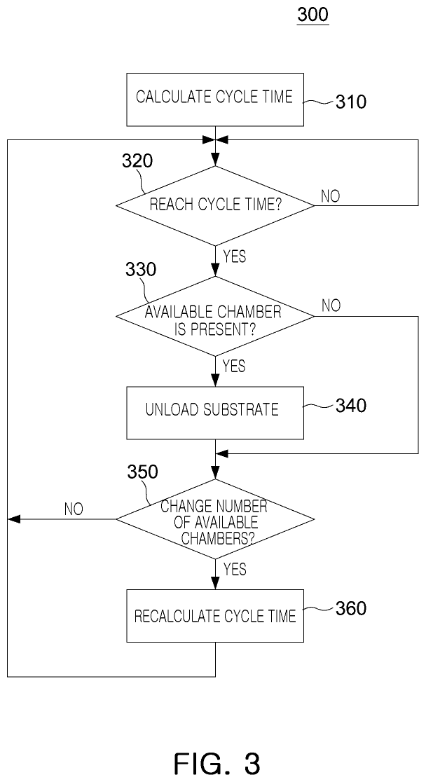

The control unit 170 may control the substrate processing apparatus 100. In particular, in an example embodiment of the present disclosure, collapse of fine patterns may occur due to humidity change of the substrate W. In order to prevent the fine patterns from collapsing, the control unit 170 may manage an unloading schedule of the substrate W so as to minimize a time during which the substrate W is exposed externally. Considering a transfer time of the substrate W by the index unit 120, a processing time of the substrate W in the first process unit 140, a processing time of the substrate W in the second process unit 150, and a conveyance time of the substrate W by the conveyance unit, the control unit 170 may calculate a desired cycle time or a time interval, and may unload the substrate W from the container at each cycle time. After unloading the substrate W, the control unit may close a door of the container 180 such that the substrate W loaded in the container 180 is not in contact with the outside of the container 180. At each cycle time, when unloading the substrate W from the container 180, the control unit 170 may verify whether an available chamber is present. When no available chamber is present, the control unit 170 may not unload the substrate W from the container 180, such that the unloaded substrate W may not be in a standby state within the substrate processing apparatus. In addition, when unloading the substrate W from the container 180 at each cycle time, the number of available chambers may be changed. In this case, the control unit may recalculate the desired cycle time, such that the substrate W may not have a standby time within the substrate processing apparatus as a state of the substrate processing apparatus is changed. An operation of the control unit 170 will be described in more detail with reference to FIGS. 3 to 9.

FIG. 2 is a schematic diagram illustrating an arrangement of process chambers of the first process unit 140 and the second process unit 150 according to an example embodiment of the present disclosure.

In an example embodiment of the present disclosure, multiple process chambers may be arranged in a row, stacked vertically, or arranged in a combination thereof. For example, as illustrated in FIG. 2, some process chambers (a first chamber, a second chamber, a third chamber), among the multiple process chambers of the first process unit 140, and other process chambers (a fourth chamber, a fifth chamber, a sixth chamber) may be disposed on both sides of the conveyance unit 160. Similarly, some process chambers (a seventh chamber, an eighth chamber, a ninth chamber), among the plurality of process chambers of the second process unit 150, and other process chambers (a tenth chamber, an eleventh chamber, a twelfth chamber) may also be disposed on both sides of the conveyance unit 160. An arrangement of the multiple process chambers 33 is not limited to the above examples, and may be changed considering a footprint or process efficiency of the substrate processing apparatus.

In an example embodiment of the present disclosure, the first process unit 140 may perform a cleaning process. In this case, the cleaning process may be general cleaning or sulfuric cleaning. In general cleaning, one of SC1, HF, LAL, or IPA, which is a cleaning solution, may be used to clean the substrate W. SC1 (Standard Cleaning 1), an ammonium peroxide mixture (APM), may be a mixture of ammonium hydroxide (NH₄OH), hydrogen peroxide (H₂O₂), and water (H₂O). In addition, LAL, also referred to as a buffered oxide etchant (BOE), may be a mixture of ammonium fluoride (NH4F) and hydrofluoric acid (HF). In addition, hydrofluoric acid (HF) and isopropyl alcohol (IPA) may also be used as cleaning solutions for the substrate W. After the substrate W is cleaned with one of SC1, HF, LAL, or IPA in a general cleaning chamber, the substrate W may be cleaned with high-temperature sulfuric acid in sulfuric cleaning so as to remove residual photoresist or other residues that have not been completely removed.

In an example embodiment of the present disclosure, the second process unit 150 may perform a drying process, which may dry the substrate W using a supercritical fluid. The supercritical fluid may be used as a drying gas in the drying process, and may dry the substrate W within the chamber. For example, carbon dioxide (CO₂) may be used as the supercritical fluid. The substrate W may be supercritical-dried by carbon dioxide having a critical temperature of 31° C. and a critical pressure of 73.8 bar. The supercritical fluid may be combined with a chemical solution or deionized water (DIW) to remove contaminants in a place in which the chemical solution or deionized water does not penetrate due to miniaturization.

FIG. 3 is a flowchart 300 illustrating an operation of the substrate processing apparatus 100 under control of the control unit 170 according to an example embodiment of the present disclosure.

First, the control unit 170 may calculate a desired cycle time or a time interval at which the index unit 120 unloads the substrate W from the container 180 (310). The desired cycle time may refer to a time interval for unloading the substrate W from the container 180 such that, after being unloaded, the substrate W may be processed by the first process unit 140 and the second process unit 150 without a standby time, and may then be loaded back into the container 180. For example, the desired cycle time may be calculated considering a transfer time of the substrate W by the index unit 120, a processing time of the substrate W in the first process unit 140, a processing time of the substrate W in the second process unit 150, and a transfer time of the substrate W by the conveyance unit 160. When considering the processing time by the first process unit 140, a larger number of available chambers in the first process unit 140 may increase the number of substrates W that may be processed by the first process unit 140. Accordingly, the processing time of the substrate W in the first process unit 140 may be divided by the number of available chambers in the first process unit 140, and a result of the division may be considered as a final processing time in the first process unit 140. Similarly, when considering the processing time in the second process unit 150, a larger number of available chambers may increase the number of substrates W that may be processed by the second process unit 150. Accordingly, the processing time of the substrate W in the second process unit 150 may be divided by the number of available chambers in the second process unit 150, and a result of the division may be considered as a final processing time in the second process unit 150.

When the desired cycle time or time interval is reached, the index unit 120 may unload the substrate W from the container 180 (320). At each cycle time, when unloading the substrate W from the container 180, whether an available chamber is present may be verified (330). When no available chamber is present, the substrate W may not be unloaded from the container 180. When an available chamber is present, the substrate W may be unloaded from the container 180 (340). In addition, when the number of available chambers is changed at each cycle time (350), the desired cycle time or time interval may be recalculated (360). In such a manner, even when a state of the substrate processing apparatus 100 is changed and the number of available chambers is reduced, the substrate W unloaded from the container 180 may not have a standby time within the substrate processing apparatus 100.

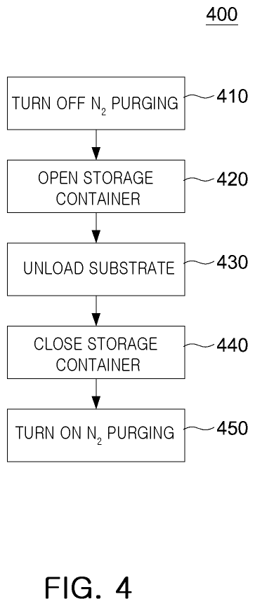

FIG. 4 is a flowchart illustrating in more detail an operation (340) of unloading a substrate W from the container 180 in an example embodiment of the present disclosure.

First, N₂ purging may be turned off (410). N₂ purging may be a process of purging gas particles within the container 180 by flowing and circulating N₂ gas within the container 180 to remove the gas particles within the container 180. To this end, a system for supplying N₂ gas to the container 180 and discharging N₂ gas from the container 180 may be established in the load port 110 of the substrate processing apparatus 100. When N₂ purging is turned off, the door of the storage container 180 may be opened (420). A system for opening and closing the door of the container 180 under the control of the control unit 170 may be established in the index unit 120.

When the door of the storage container 180 is opened, the substrate W loaded in the container 180 may be unloaded by the index robot of the index unit 120 (430). After the substrate W is unloaded, the door of the container 180 may be closed to prevent the substrate W loaded in the container 180 from being exposed to the outside of the container 180 (440). After the door of the container 180 is closed, N₂ purging may be performed again to remove the gas particles within the container 180 (450).

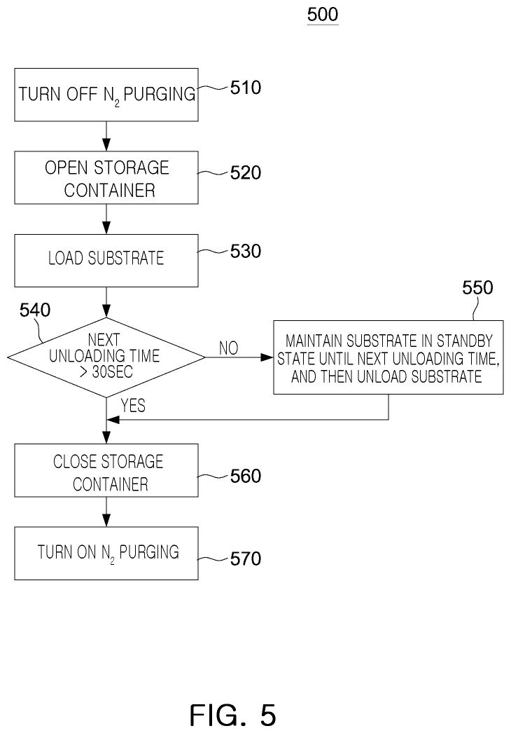

FIG. 5 is a flowchart (500) illustrating a process of loading the substrate W processed by the substrate processing apparatus 100 into the container 180 in an example embodiment of the present disclosure.

First, N₂ purging may be turned off (510). After N₂ purging is turned off, the door of the storage container 180 may be opened (520). When the door of the storage container 180 is opened, the substrate W processed by the first process unit 140 and the second process unit 150 may be transferred by the index robot of the index unit 120 and loaded into the storage container 180 (530). After the substrate W is loaded into the storage container 180, a next cycle time may be checked (540). When a remaining time until the next cycle time is greater than a predetermined time (for example, several to several tens of seconds), the door of the storage container 180 may be closed without a standby time until the next cycle time (560). A time during which the substrate W loaded in the container 180 is in contact with the outside of the container 180 may be minimized by closing the door of the container 180. When the remaining time until the next cycle time is less than the predetermined time (for example, 30 seconds), the substrate W may be in a standby state until the next cycle time. When the next cycle time is reached, the substrate W may be unloaded (550), and the door of the storage container 180 may be closed after the substrate W is unloaded. That is, when an operation of unloading the substrate W after loading the substrate W into the container 180 is followed, the door of the container 180 may be efficiently turned on/off by maintaining the door of the container 180 in an open state without performing the inefficient operation of closing and reopening the door of the container 180, thereby minimizing an operation time of the door of the container 180.

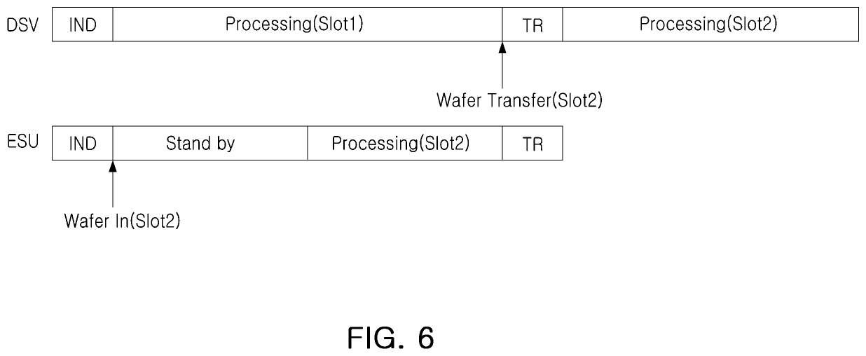

FIG. 6 is a schematic diagram illustrating an operation of unloading a substrate W from a container in a substrate processing apparatus according to the related art. In FIG. 6, an exquisite spin unit (ESU) may correspond to the first process unit of an example embodiment of the present disclosure, and a dryer with supercritical-fluid vessel (DSV) may correspond to the second process unit of an example embodiment of the present disclosure. In the substrate processing apparatus according to the related art, a substrate (slot2) unloaded from a container may be moved to the ESU. The substrate (slot2) may be in a standby state in the ESU. Considering a processing time of another substrate (slot1) in the DSV, processing of the substrate (slot2) in the ESU may be completed such that a point in time at which processing of the substrate (slot2) in the ESU is completed aligns with a point in time at which processing of another substrate (slot1) in the DSV is completed. After processing of the substrate (slot2) in the ESU is completed, the substrate (slot2) for which processing of the ESU is completed may be moved to the DSV. In the substrate processing apparatus according to the related art, the substrate W may be in a standby state in the ESU, which may cause an increase in use of a chemical solution and the occurrence of edge defects.

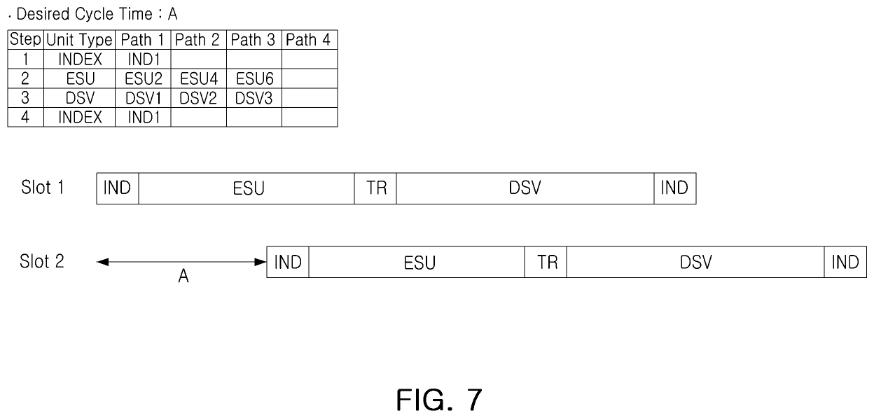

FIG. 7 is a schematic diagram illustrating an operation of unloading the substrate W from the container 180 in the substrate processing apparatus 100 according to an example embodiment of the present disclosure. In the substrate processing apparatus 100 according to an example embodiment of the present disclosure, a desired cycle time or time interval for unloading the substrate W from the container 180 may be calculated. The table in FIG. 7 illustrates an example in which one cycle of the substrate W in the substrate processing apparatus 100 includes four steps: a first step of indexing (INDEX), a second step of first process (ESU), a third step of second process (DSV), and a fourth step of indexing (INDEX). That is, unloading the substrate W from the container 180 by the index unit may be the first step, processing the substrate W by the first process unit may be the second step, processing the substrate W by the second process unit may be the third step, and loading the substrate W back into the container 180 by the index unit may be the fourth step. The desired cycle time may be determined based on a time required for each step or a processing time. In this case, the number of available chambers of the first process unit may be three (ESU2, ESU4, and ESU6) in the second step, and the number of available chambers of the second process unit may be three (DSV1, DSV2, and DSV3) in the third step. When the number of available chambers increases, the number of substrates W that may be processed may increase. Accordingly, processing times for the first and second process units for each substrate W may be reduced. Thus, final processing times of the first and second process units may be determined by dividing the processing times of the first and second process units by the numbers of available chambers of the respective process units. The determined desired cycle time is illustrated as A seconds (A being in a range of several to several tens of seconds). The timing diagram in FIG. 7 illustrates that the substrate W is unloaded from the container 180 and processed at an interval of A seconds.

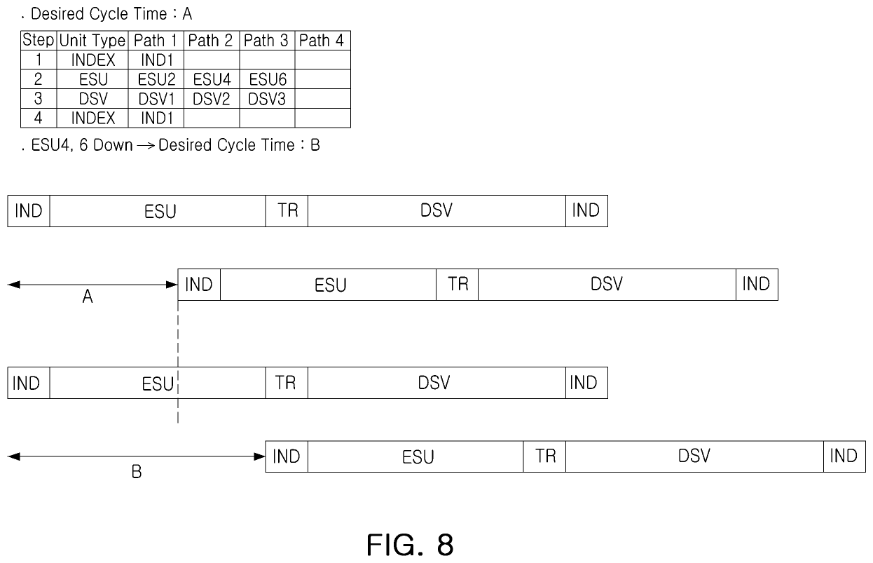

FIG. 8 is a schematic diagram illustrating an operation of unloading the substrate W from the container 180 in the substrate processing apparatus 100 according to an example embodiment of the present disclosure. In the substrate processing apparatus 100 according to an example embodiment of the present disclosure, when a state of the substrate processing apparatus 100 is changed, a desired cycle time or time interval for unloading the substrate W from the container 180 may be recalculated. The table in FIG. 8 illustrates a case in which, as compared to the table in FIG. 7, the process chambers (ESU4 and ESU6) in the second step of the first process unit 140 are down, and the number of available chambers is changed to one (ESU2). As the number of available chambers of the first process unit 140 is reduced, the number of substrates W that may be processed by the first process unit 140 may be reduced. Accordingly, the desired cycle time may be recalculated, reflecting a reduction in the number of available chambers of the first process unit. The recalculated desired cycle time is illustrated to be increased to B seconds (B>A). The timing diagram in FIG. 8 illustrates that, before the chambers (ESU4 and ESU6) in the substrate processing apparatus 100 are down, the substrate W is unloaded from the container 180 and processed at an interval of 77.66 seconds. After the chambers (ESU4 and ESU6) are down, the substrate W is unloaded from the container 180 and processed at an interval of 129.5 seconds.

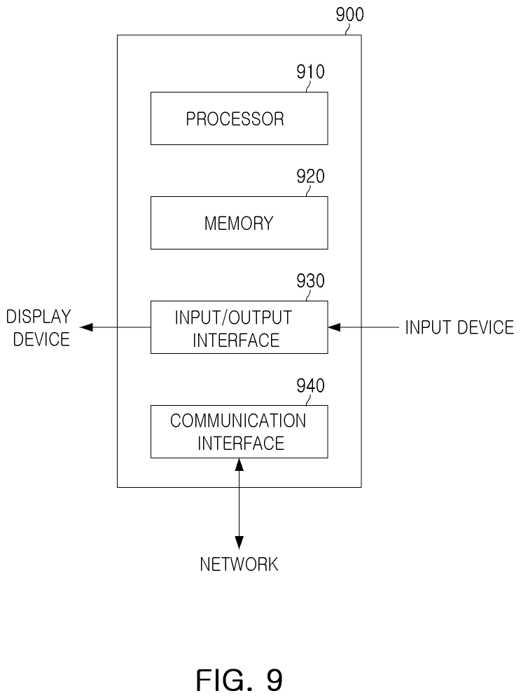

FIG. 9 is a block diagram illustrating a computing device 900 capable of fully or at least partially implementing the controller 170 of the substrate processing apparatus 100 according to an example embodiment of the present disclosure.

First, referring to FIG. 9, the computing device 900 according to an example embodiment of the present disclosure may include a processor 910, a memory 920, an input/output interface 930, and a communication interface 940. However, the present disclosure is not limited thereto, and the computing device 900 may further include other components, or some components may be omitted. Some of the components of the computing device 900 may be divided into a plurality of devices, or a plurality of components may be merged into a single device.

In an example embodiment of the present disclosure, the memory 920, a computer-readable recording medium, may include a random access memory (RAM), a read only memory (ROM), and a permanent mass storage device such as a disk drive. In addition, a program code for controlling the substrate processing apparatus 100 may be temporarily or permanently stored in the memory 920. For example, the memory 920 may include a scheduling program code for unloading the substrate W from the container 180 in an example embodiment of the present disclosure.

The processor 910 may be configured to control the substrate processing apparatus 100 according to a program code stored in a recording device such as the memory 920 such that the substrate processing apparatus 100 performs the above-described operations according to example embodiments. The processor 910 may access a network through the communication interface 940, and may communicate with an external device.

To this end, the communication interface 940 may provide a function for communicating with an external device through a network. The communication method is not limited, and may include not only a communication method using a communication network included in the network (for example, a mobile communication network, a wired Internet, a wireless Internet, or a broadcasting network) but also a short-range wireless communication method between devices. For example, the communication method according to an example embodiment of the present disclosure may be a communication method using orthogonal frequency division multiplexing (OFDM). The network may include any one or more networks such as a personal area network (PAN), a local area network (LAN), a campus area network (CAN), a metropolitan area network (MAN), a wide area network (WAN), a broadband network (BBN), or the Internet. In addition, the network may include any one or more types of network topology, such as a bus network, a star network, a ring network, a mesh network, a star-bus network, a tree network, or a hierarchical network, but the present disclosure is not limited thereto.

In addition, the computing device 900 according to an example embodiment of the present disclosure may include the input/output interface 930. The input/output interface 930 may be a means for an interface with an input/output device. For example, an input device may include a keyboard or a mouse, and an output device may include a display for displaying an operation of an application. For another example, the input/output interface 930 may also be a means for an interface with a device in which functions for input and output are integrated into a single function, such as a touchscreen.

In addition, in other example embodiments, the computing device 900 may include more components than those illustrated in FIG. 9. For example, the computing device 900 may be implemented to include at least some of the above-described input/output devices, or may further include other components such as a battery and a charging device supplying power to internal components, various sensors, and a database.

The example embodiment of the present disclosure described above is a case in which the first process unit and the second process unit perform a cleaning process and a drying process, respectively. However, the present disclosure is not limited thereto, and may also be applied to a case in which the first process unit and the second process unit perform other processes. In addition, although the substrate processing apparatus according to an example embodiment of the present disclosure includes two process units, that is, the first process unit and the second process unit, the present disclosure is not limited thereto, and may also be applied to a case in which the substrate processing apparatus includes three or more process units.

Although example embodiments of the present disclosure have been described above with reference to the accompanying drawings, it will be understood by those skilled in the art that the present disclosure may be embodied in other specific forms without changing the technical spirit or essential features thereof. Therefore, it should be understood that the example embodiments described above are illustrative in all respects and not restrictive.

What is claimed is:

1. A substrate processing apparatus comprising:
an index unit configured to unload a substrate from a container storing the substrate; and
a control unit configured to control the index unit,
wherein the index unit is configured to unload the substrate from the container at a predetermined time interval, and to close a door of the container after unloading the substrate.

2. The substrate processing apparatus of claim 1, wherein the index unit is configured to not unload the substrate from the container, when no available chamber is present at a point in time at which the index unit unloads the substrate from the container.

3. The substrate processing apparatus of claim 1, wherein the control unit is configured to reset the predetermined time interval, when the number of available chambers is changed at a point in time at which the index unit unloads the substrate from the container.

4. The substrate processing apparatus of claim 1, wherein
the substrate processing apparatus further includes a first process unit and a second process unit, and
the control unit is configured to determine the predetermined time interval, based on a processing time of the index unit, a processing time of the first process unit, and a processing time of the second process unit.

5. The substrate processing apparatus of claim 4, wherein the control unit is configured to determine the processing time of the first process unit, based on the number of available chambers of the first process unit.

6. The substrate processing apparatus of claim 4, wherein the control unit is configured to determine the processing time of the second process unit, based on the number of available chambers of the second process unit.

7. The substrate processing apparatus of claim 4, wherein the index unit is configured to load a substrate processed by the first process unit and the second process unit into a storage container, to maintain the substrate in a standby state until a unloading time of a subsequent substrate without closing a door of the container when a remaining time until the unloading time of the subsequent substrate is less than a predetermined time after loading the substrate, and to unload the substrate at the unloading time of the subsequent substrate and then close the door of the container.

8. A substrate processing method comprising:
determining a predetermined time interval;
unloading a substrate from a container storing the substrate at the predetermined time interval; and
closing a door of the container after unloading the substrate.

9. The substrate processing method of claim 8, further comprising:
not unloading the substrate when no available chamber is present in a substrate processing apparatus at a point in time at which the substrate is unloaded from the container.

10. The substrate processing method of claim 8, further comprising:
resetting the predetermined time interval, when the number of available chambers in the substrate processing apparatus is changed at a point in time at which the substrate is unloaded from the container.

11. The substrate processing method of claim 8, wherein the predetermined time interval is determined based on a time during which the substrate is unloaded from the container and transferred in the substrate processing apparatus, and a time during which the substrate is processed by a predetermined process of the substrate processing apparatus.

12. The substrate processing method of claim 11, wherein the predetermined time interval is determined based on the number of available chambers of the substrate processing apparatus.

13. The substrate processing method of claim 11, wherein a substrate, processed by a process unit, is loaded into a storage container, is maintained in a standby state until a unloading time of a subsequent substrate without closing a door of the container when a remaining time until the unloading time of the subsequent substrate is less than a predetermined time after the substrate is loaded, and is unloaded at the unloading time of the subsequent substrate and then the door of the container is closed.

14. A substrate processing apparatus comprising:
a processor; and
a memory storing an instruction executed by the processor,
wherein, when the processor executes the instruction stored in the memory, the processor is configured to:
unload a substrate from a container storing the substrate at a predetermined time interval, and
close a door of the container such that a substrate remaining in the container is not in contact with the outside of the container, after unloading the substrate.

15. The substrate processing method of claim 14, wherein the processor is configured to not unload the substrate, when no available chamber is present at a point in time at which the substrate is unloaded from the container.

16. The substrate processing method of claim 14, wherein the processor is configured to reset the predetermined time interval when the number of available chambers is changed at a point in time at which the substrate is unloaded from the container.

17. The substrate processing method of claim 14, wherein
the substrate processing apparatus includes an index unit, a first process unit, and a second process unit, and
the processor is configured to determine the predetermined time interval, based on a processing time of the index unit, a processing time of the first process unit, and a processing time of the second process unit.

18. The substrate processing method of claim 17, wherein the processor is configured to determine the processing time of the first process unit, based on the number of available chambers of the first process unit.

19. The substrate processing method of claim 17, wherein the processor is configured to determine the processing time of the second process unit, based on the number of available chambers of the second process unit.

20. The substrate processing method of claim 17, wherein the processor is configured to load a substrate processed by the first process unit and the second process unit into a storage container, to maintain the substrate in a standby state until a unloading time of a subsequent substrate without closing a door of the container when a remaining time until the unloading time of the subsequent substrate is less than a predetermined time after loading the substrate into the storage container, and to unload the substrate at the unloading time of the subsequent substrate and then close the door of the container.
